(19) United States
(12) Patent Application Publication
(10) Pub. No.: US 2011/0215462 A1
(43) Pub. Date: Sep. 8, 2011

(54) SEMICONDUCTOR DEVICE AND MANUFACTURING METHOD THEREOF

(75) Inventor: Fumiyoshi KAWASHIRO, Kanagawa (JP)

(73) Assignee: RENESAS ELECTRONICS CORPORATION

(21) Appl. No.: 13/040,469

(22) Filed: Mar. 4, 2011

(30) Foreign Application Priority Data
Mar. 8, 2010 (JP) 2010-051068

(51) Int. Cl. H01L 23/34; H01L 21/60

(52) U.S. Cl. 257/693; 438/460; 257/E21.508; 257/E23.08

(57) ABSTRACT

A method of manufacturing semiconductor devices is provided, in which a resin sealing structure includes an interconnection substrate board, semiconductor chips, a heat radiation plate, and sealing resin. The method is achieved by cutting the heat radiation plate by a plate cutting blade in a first direction along a first heat radiation plate cutting line; by cutting the heat radiation plate by the plate cutting blade in a second direction along a second heat radiation plate cutting line, after cutting in the first direction by the plate cutting blade; and by cutting the interconnection substrate board and the sealing resin along first and second interconnection substrate board cutting lines by a substrate board cutting blade in the first direction and the second direction, respectively. The second heat radiation plate cutting line and the second interconnection substrate board cutting line correspond to each other in position in a third direction orthogonal to the first direction and the second direction. The first heat radiation plate cutting line is displaced from the first interconnection substrate board cutting line by a preset displacement amount in a direction opposite to the second direction.

### INCORPORATION BY REFERENCE

This patent application claims a priority on convention based on Japanese Patent Application No. 2010-051068 filed on Mar. 8, 2010. The disclosure thereof is incorporated herein by reference.

### TECHNICAL FIELD

The present invention relates to a semiconductor device and a method of manufacturing the same.

As one type of semiconductor device, a BGA (Ball Grid Array) type of semiconductor device is known. This type of semiconductor device is provided with an interconnection substrate, a semiconductor chip, wires, sealing resin, a heat radiator (also, to be referred to as a “heat spreader”) and a group of ball-shaped electrodes.

A method of manufacturing a MAP (Mold Array Package) type of semiconductor device is known. In this type, a semiconductor chip is mounted on a front surface of an interconnection substrate. Wire bonding is performed on the front surface of the interconnection substrate so that the interconnection substrate and the semiconductor chip are electrically connected by wires. A heat radiator is arranged above the semiconductor chip to face the front surface of the interconnection substrate. Sealing resin is injected between the interconnection substrate and the heat radiator. When the sealing resin is hardened, a resin sealing structure is formed in which the semiconductor chip and the wires are sealed with the sealing resin between the interconnection substrate and the heat radiator. The group of ball-shaped electrodes is formed on a back surface of the interconnection substrate.

Thereafter, the resin sealing structure is cut out by a disc-shaped blade from a side of the back surface of the interconnection substrate. By cutting out the resin sealing structure in a matrix shape, a plurality of semiconductor devices are obtained.

Patent Literature 1 (JP H11-214596A) is exemplified as a technique disclosing a technique relating to the MAP type of semiconductor device. Further, in Patent Literature 2 (JP 2006-294832A), there is disclosed a technique relating to a method of forming a heat radiator. In Patent Literature 3 (JP 2003-249512A), it is described that the resin sealing structure as a whole is cut using a disc-shaped blade. Also, in Patent Literature 4 (JP 2000-183218A), Patent Literature 5 (JP 2003-37236A) and Patent Literature 6 (JP H04-307961A), there is disclosed a technique of cutting.

### CITATION LIST

[Patent Literature 1]: JP H11-214596A
[Patent Literature 2]: JP 2006-294832A
[Patent Literature 3]: JP 2003-249512A
[Patent Literature 4]: JP 2000-183218A
[Patent Literature 5]: JP 2003-37236A
[Patent Literature 6]: JP H04-307961A

### SUMMARY

However, when the resin sealing structure is cut out at once by a blade from a side of the interconnection substrate, burr is formed at a cut edge section because the heat radiator (of copper, for example) is soft and malleable. Since the burr is conductive, a short circuit may be possibly formed between the electrodes or between the interconnections of the implementation board, if the semiconductor device is mounted on an implementation board with the burr or a flake of a peeled burr adhered to the semiconductor device. Therefore, it is necessary to suppress the protrusion of burr.

In an aspect of the present invention, a method of manufacturing semiconductor devices is provided, in which a resin sealing structure includes an interconnection substrate board, semiconductor chips mounted on the interconnection substrate board, a heat radiation plate arranged above semiconductor chips, and sealing resin provided between the heat radiation plate and the interconnection substrate board. The method is achieved by cutting the heat radiation plate by a plate cutting blade in a first direction along a first heat radiation plate cutting line; by cutting the heat radiation plate by the plate cutting blade in a second direction orthogonal to the first direction along a second heat radiation plate cutting line orthogonal to the first heat radiation plate cutting line, after cutting in the first direction by the plate cutting blade; and by cutting the interconnection substrate board and the sealing resin along first and second interconnection substrate board cutting lines by a substrate board cutting blade in the first direction and the second direction, respectively, to divide the resin sealing structure into the semiconductor devices, each of which comprises an interconnection substrate, the semiconductor chip mounted on the interconnection substrate, the sealing resin provided to cover the semiconductor chip and the interconnection substrate, and a heat radiator. The second heat radiation plate cutting line and the second interconnection substrate board cutting line correspond to each other in position in a third direction orthogonal to the first direction and the second direction. The first heat radiation plate cutting line is displaced from the first interconnection substrate board cutting line by a preset displacement amount in a direction opposite to the second direction.

In another aspect of the present invention, a semiconductor device includes a semiconductor chip mounted on a front surface of an interconnection substrate; a heat radiator arranged above the semiconductor chip; and sealing resin provided between the heat radiator and the interconnection substrate. A center of the heat radiator is displaced from a center of the interconnection substrate by a preset displacement amount in a predetermined direction.

According to the present invention, when the heat radiator is cut, it is possible to prevent burr of the heat radiator from protruding rather than the position of the interconnection substrate while suppressing the burr of the heat radiator extending in a direction from the heat radiator toward the interconnection substrate and the burr of the heat radiator extending in a direction from the interconnection substrate toward the heat radiator.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a sectional view showing a configuration of a semiconductor device according to an embodiment of the present invention;

FIG. 2 is a flow chart showing a method of manufacturing the semiconductor device according to the embodiment of the present invention;

FIG. 3A is a top view of an interconnection substrate board in a manufacturing method according to the embodiment of the present invention;

FIG. 3B is a sectional view of the interconnection substrate board and semiconductor chips in the manufacturing method according to the embodiment of the present invention;

FIG. 3C is a sectional view of the interconnection substrate board, the semiconductor chips and bonding wires in the manufacturing method according to the embodiment of the present invention;

FIG. 3D is a sectional view of a resin sealing structure in the manufacturing method according to the embodiment of the present invention;

FIG. 3E is a top view of the heat radiation plate in the manufacturing method according to the embodiment of the present invention;

FIG. 3F is a top view of the resin sealing structure showing at a time of cutting the heat radiation plate in a first direction X and a second direction Y in the manufacturing method according to the embodiment of the present invention;

FIG. 3G is a sectional view of the resin sealing structure at a time of cutting the heat radiation plate cutting in the second direction Y in the manufacturing method according to the embodiment of the present invention;

FIG. 3H is a sectional view of the resin sealing structure and a group of ball-shaped electrodes in the manufacturing method according to the embodiment of the present invention;

FIG. 3I is a sectional view of the resin sealing structure and the group of ball-shaped electrodes at a time of cutting the interconnection substrate board in the second direction Y in the manufacturing method according to the embodiment of the present invention;

FIG. 3J is a sectional view of the semiconductor device which includes a interconnection substrate, the semiconductor chip, the bonding wires, the sealing resin, the heat radiator and the group of ball-shaped electrodes, in the manufacturing method according to the embodiment of the present invention;

FIG. 3K is an enlarged view showing a neighborhood of burr shown in FIG. 3F;

FIG. 4A is a sectional view of the resin sealing structure in a comparison example to the present invention;

FIG. 4B is a top view of the resin sealing structure at a time of cutting the heat radiation plate in the first direction X and the second direction Y in the comparison example;

FIG. 4C is a sectional view of the resin sealing structure seeing at a time of cutting the heat radiation plate in the second direction Y in the comparison example;

FIG. 4D is a sectional view of the resin sealing structure and the group of ball-shaped electrodes in the comparison example;

FIG. 4E is a sectional view of the resin sealing structure and the group of ball-shaped electrodes at a time of cutting the interconnection substrate in the second direction Y of the interconnection substrate in the comparison example; and

FIG. 4F is a perspective sectional view of the semiconductor device in the comparison example.

### DETAILED DESCRIPTION

Hereinafter, a semiconductor device according to the present invention will be described below in detail with reference to the attached drawings.

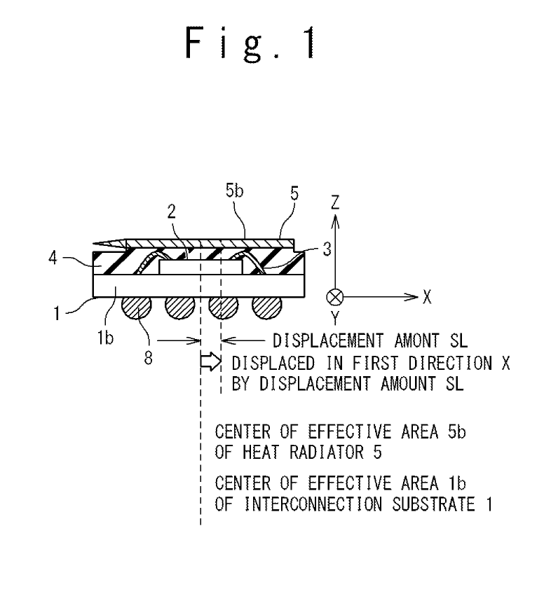

FIG. 1 is a sectional view showing a structure of a semiconductor device according to an embodiment of the present invention. The semiconductor device according to the embodiment of the present invention includes an interconnection substrate 1, a semiconductor chip 2, bonding wires 3, sealing resin 4, a heat radiator 5 and a group of ball-shaped electrodes 8.

The semiconductor chip 2 is mounted on a front surface of the interconnection substrate 1. The bonding wires 3 electrically connect the interconnection substrate 1 and the semiconductor chip 2. The heat radiator 5 is placed above the semiconductor chip 2. The sealing resin 4 is provided between the interconnection substrate 1 and the heat radiator 5 to seal the semiconductor chip 2 and the bonding wires 3 therewith. A group of the ball-shaped electrodes 8 are formed on a back surface of the interconnection substrate 1. A center of the heat radiator 5 (i.e., a center of an effective region 5b to be described later) is displaced from a center of the interconnection substrate 1 (i.e., a center of an effective region 1b to be described later) by a preset displacement amount SL in a first direction X. It is noted that burr formed at a time of cutting the heat radiation plate 5′ is shown as a triangle at a left edge of the heat radiator 5 in FIG. 1. Moreover, the bonding wires 3 and the group of the ball-shaped electrodes 8 are electrically connected through interconnections formed in the interconnection substrate 1, although not shown.

As the interconnection substrate 1, a glass epoxy board and the like is used, and it is formed by laminating insulating layers of glass fibers impregnated with resin and copper interconnection layers, in this embodiment. The thickness of the interconnection substrate 1 is 0.3 to 0.6 mm in this embodiment.

The sealing resin 4 functions to protect the semiconductor chip 2 and bond the heat radiator 5. The thickness of the sealing resin 4 is 0.3 to 1.2 mm in this embodiment.

The heat radiator 5 is also referred to as “a heat spreader” that may be also denoted as H/Sp. The heat radiator 5 is provided to dissipate heat generated by the semiconductor chip 2. As the heat radiator 5, a metal plate is preferably used from the viewpoint of thermal conductivity. More specifically, the material of the heat radiator 5 is such as copper, aluminum, iron and the like. The thickness of the heat radiator 5 is 0.1 to 0.5 mm in this embodiment. Moreover, a surface of the heat radiator may have a film. For example, a surface coating may be applied and a surface treatment such as an anodized aluminum treatment may be applied.

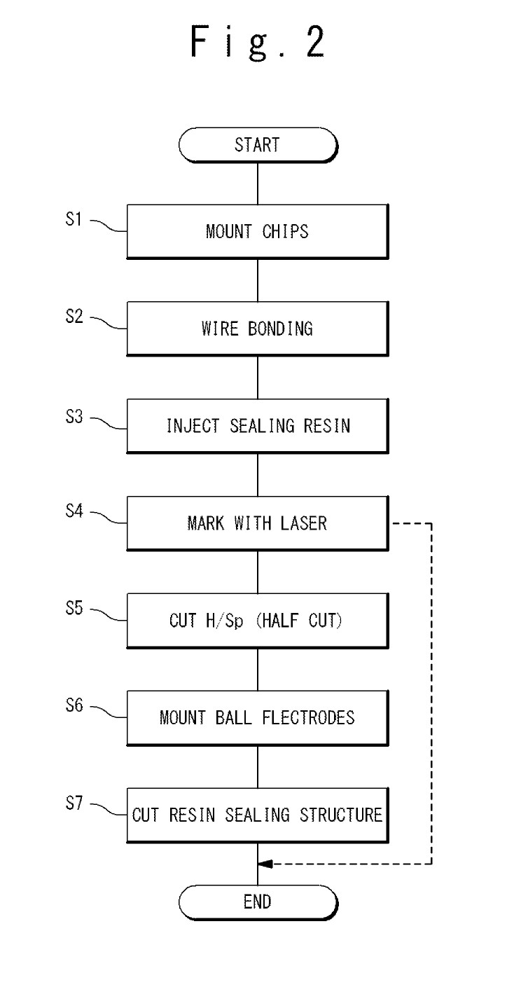

FIG. 2 is a flow chart showing a method of manufacturing the semiconductor device according to the embodiment of the present invention.

### (Step S1: Chip Mounting)

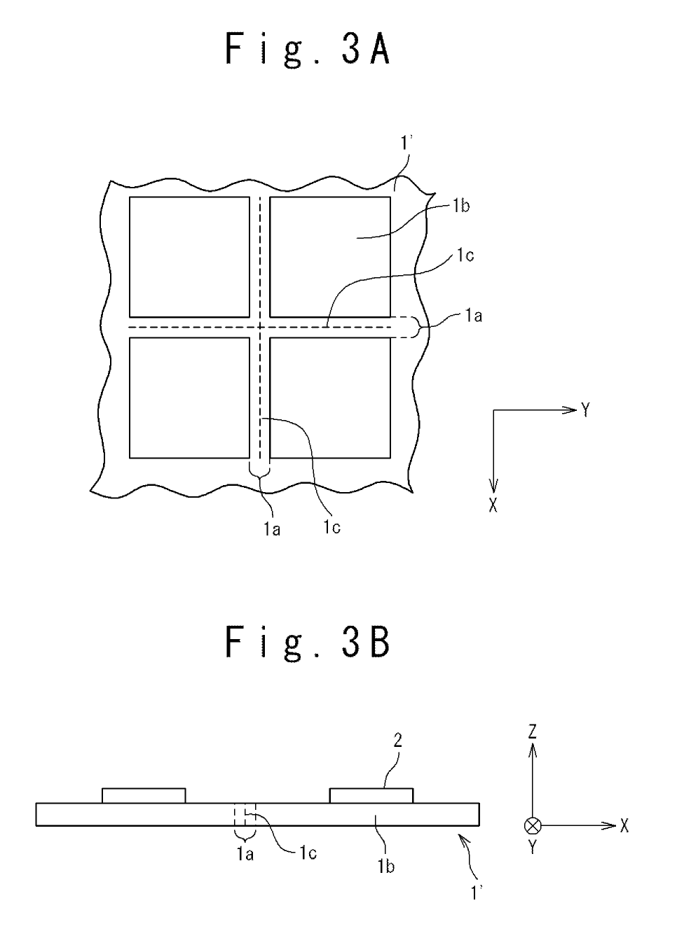

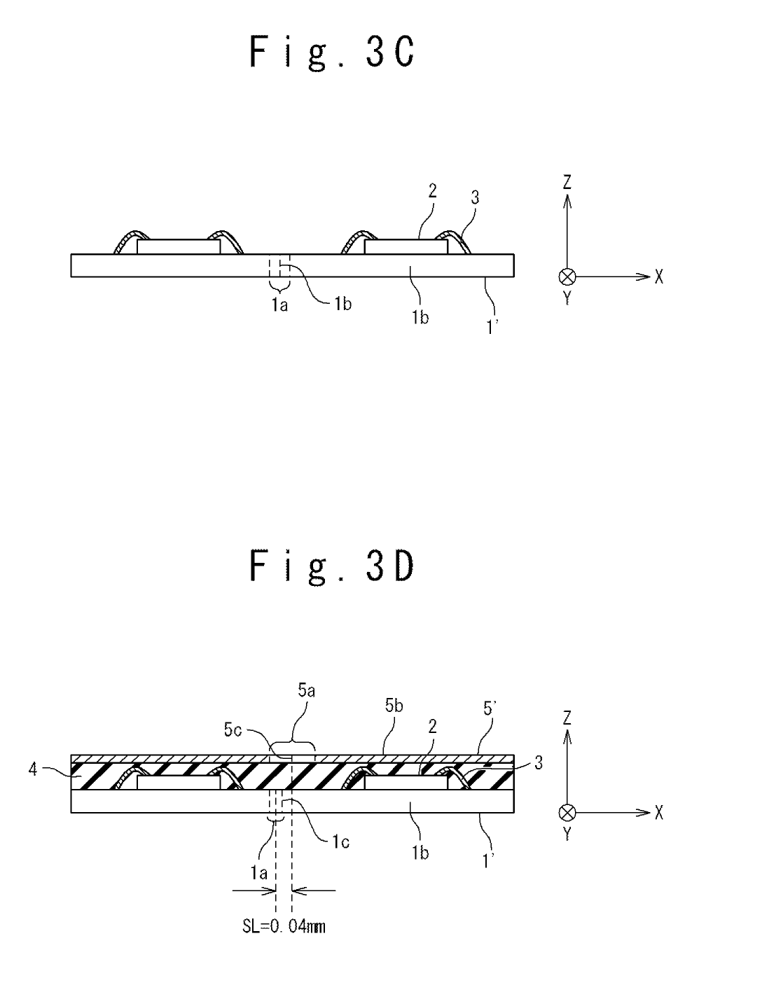

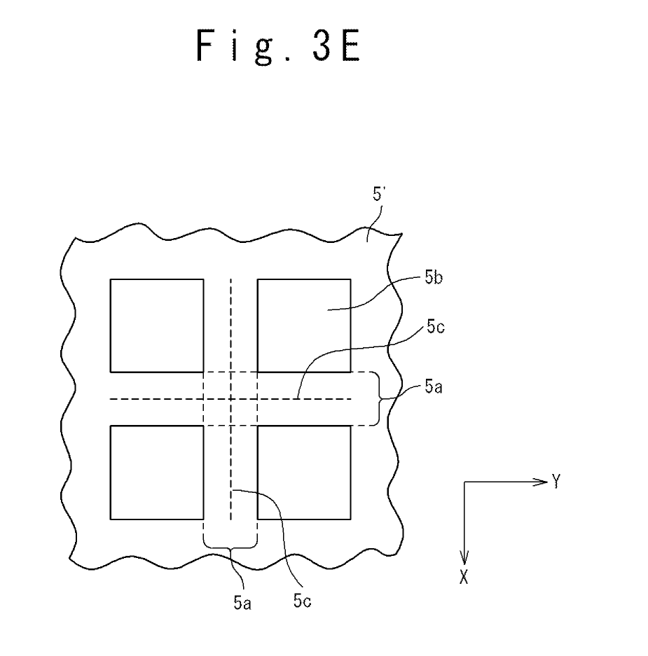

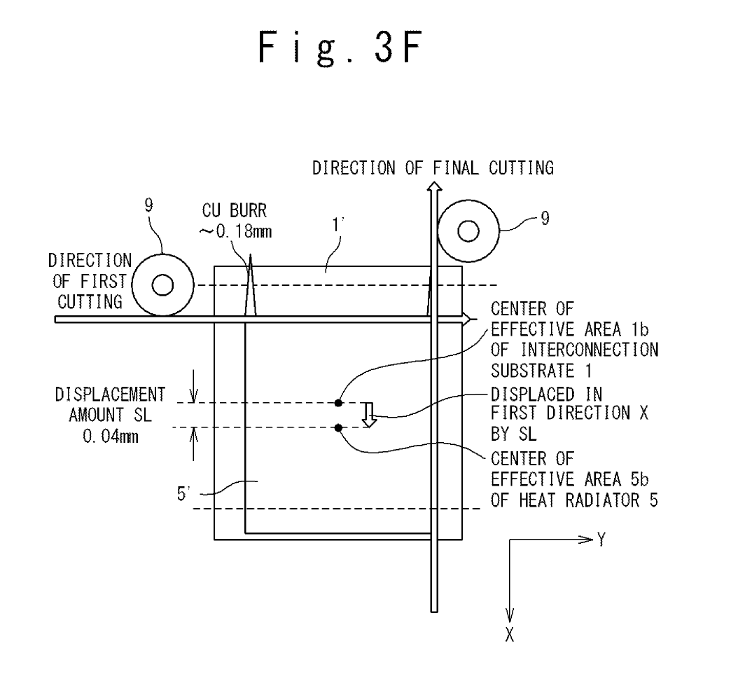

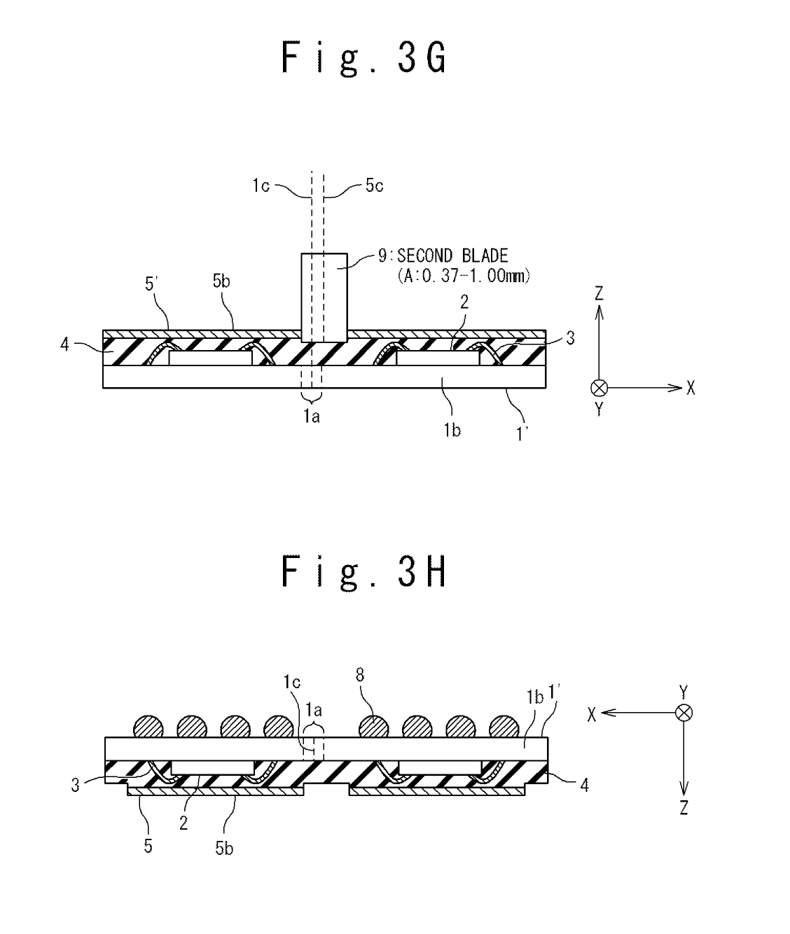

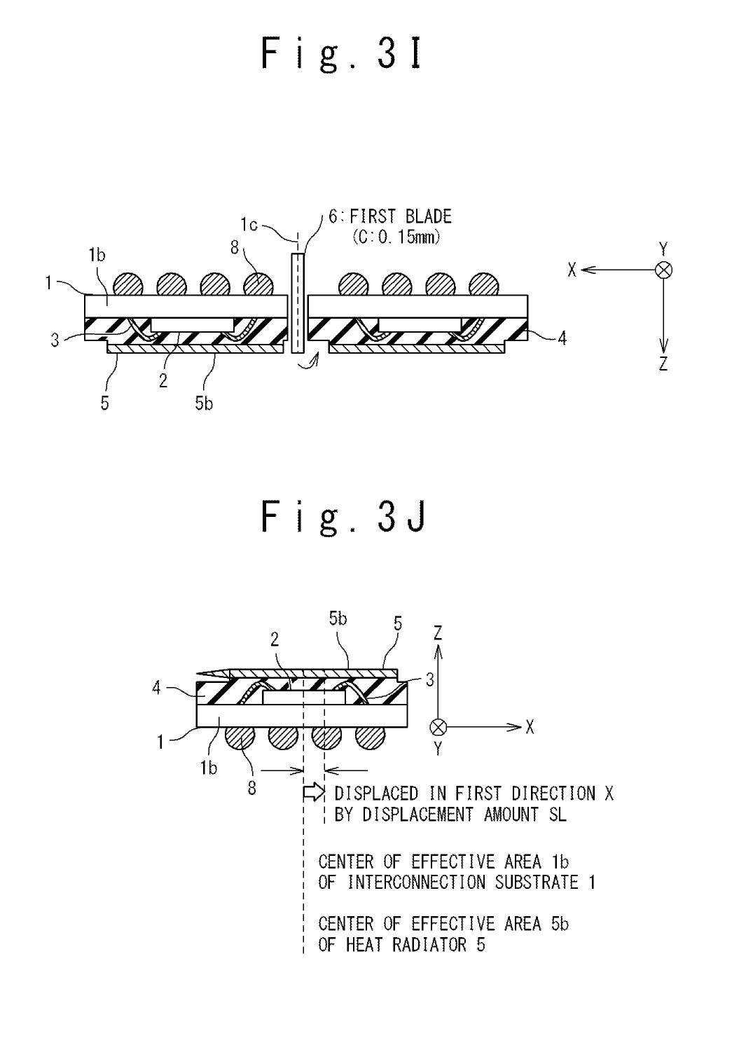

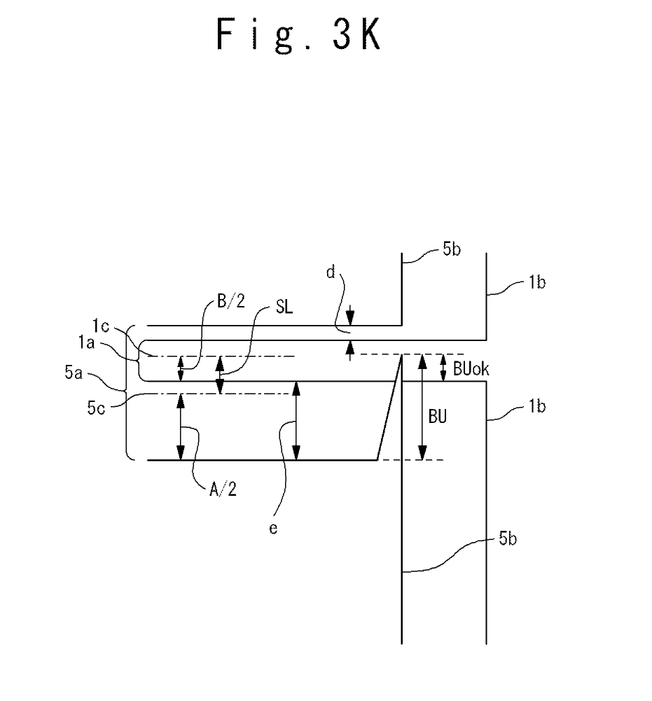

Initially, an interconnection substrate board 1′ is prepared as shown in FIG. 3A. The interconnection substrate board 1′ includes a region 1a and effective regions 1b. The region 1a is for interconnection substrate board cutting lines 1c extending in a first direction X and a second direction Y perpendicular to the first direction X. The effective regions 1b are regions of the interconnection substrate board 1′ other than the region 1a. In FIG. 3A, the region 1a and the effective regions 1b are schematically illustrated and it is not necessary to actually illustrate the interconnection substrate board cutting lines 1c and the effective regions 1b on the interconnection substrate board 1′ The width of the region 1a extending in the first direction X and the second direction Y corresponds to the thickness of a disc-shaped blade (first blade 6) to be described later, and is a region to be removed by the first blade 6. The effective regions 1b are regions that remain after the interconnection substrate board 1′ is cut by the first blade 6. Next, as shown in FIG. 3B, the semiconductor chips 2 are mounted on the front surfaces of the effective regions 1b of the interconnection substrate board 1′. A third direction Z is perpendicular to the first and second directions X and Y.

### (Step S2: Wire Bonding)

As shown in FIG. 3C, wire bonding is performed so that the effective regions 1b of the interconnection substrate board 1′ and the semiconductor chips 2 are electrically connected by the bonding wires 3.

### (Step S3: H/Sp Forming and Sealing)

As shown in FIG. 3D, the heat radiation plate 5′ is placed above the semiconductor chips 2 and the bonding wires 3 in the third direction Z to oppose to the front surface of the interconnection substrate board 1′.

As shown in FIG. 3E, the heat radiation plate 5′ includes a region 5a and effective regions 5b. The region 5a is for heat radiation plate cutting lines 5c extending in the first direction X and the second direction Y, and the effective regions 5b are regions of the heat radiation plate 5′ other than the region 5a. In FIG. 3E, it is not necessary to actually illustrate the lines 5b and 5c on the heat radiation plate 5′. The region 5a extending in the first direction X and the second direction Y corresponds to the thickness of a disc-shaped blade (second blade 9) to be described later and is a region to be cut by the second blade 9. The effective regions 5b are regions that remain after the heat radiation plate 5′ is cut by the second blade 9. A center of the region 5a extending in the first direction X is coincident with a center of the region 1a extending in the first direction X. As shown in FIG. 3D, the center of the region 5a extending in the second direction Y is displaced from the center of the region 1a extending in the second direction Y by the preset displacement amount SL in the first direction X.

Next, as shown in FIG. 3D, the sealing resin 4 is injected and provided between the interconnection substrate board l′ and the heat radiation plate 5′. When the sealing resin 4 is hardened, a resin sealing structure is formed in which the semiconductor chips 2 and the bonding wires 3 are sealed with the sealing resin 4 between the interconnection substrate board 1′ and the heat radiation plate 5′

### (Step S4: Laser Marking)

A pattern is marked with a laser on the surface of the effective region 5b of the heat radiation plate 5′.

### (Step S5: H/Sp Cutting)

### First Heat Radiation Plate Cutting Process

As shown in FIGS. 3F and 3G, in order to cut the resin sealing structure in the second direction Y, the heat radiation plate 5′ is cut by the second disc-shaped blade 9 along the heat radiation plate cutting line 5c extending in the second direction Y. The cutting direction may be either the second direction Y (arrow direction from the left toward the right in the figure) or a direction opposite to the second direction Y (from the right toward the left in the figure). Here, the heat radiation plate 5′ is cut by the second blade 9 in a state that the center of the region 5a extending in the second direction Y is displaced from the center of the region 1a extending in the second direction Y by a preset displacement amount SL in the first direction X.

### (Second Heat Radiation Plate Cutting)

Next, as shown in FIG. 3F, in order to divide the resin sealing structure in a direction opposite to the first direction X, the heat radiation plate 5′ is cut by the second blade 9 along the heat radiation plate cutting line 5c in the direction opposite to the first direction X. Here, the heat radiation plate 5′ is cut by the second blade 9 in a state that the center of the region 5a extending in the first direction X is coincident with the center of the region 1a extending in the first direction X.

In the H/Sp cutting process (Step S5), the first blade 6 is required to cut away the malleable heat radiation plate 5′ Therefore, in order to prevent the second blade 9 from clogging, the second blade 9 has a cutting edge provided with grinding grain such as diamond grains (not shown) which are coarser (have larger diameters) than those of the first blade 6. Or, a blade may have a cutting edge provided with grinding grains adhered by thermosetting resin. The shape of the cutting edge of the second blade 9 may be round (not shown). Alternatively, the shape of the cutting edge of the second blade 9 may be sharpened and its tip may be V-character shaped (not shown).

Also, in the H/Sp cutting process (Step S5), a cutting depth D (mm) when the resin sealing structure is cut from a side of the heat radiation plate 5′ is preferably not so deep as to reach the interconnection substrate board 1′. For example, the cutting depth is preferably equal to or smaller than “the thickness (mm) of the heat radiation plate 5′+0.2 (mm)” (not shown). As discussed above, it is preferable to use the blade with the grinding grains arranged densely, as the second blade 9. If the sealing resin 4 is cut away by the second blade 9, the second blade 9 may be clogged in some cases. If the depth D is set to be equal to or smaller than “the thickness (mm) of the heat radiation plate 5′+0.2 (mm)”, the sealing resin 4 to be cut by the second blade 9 can be sufficiently reduced and the second blade 9 can be prevented from clogging.

### (Step S6: Ball Mounting)

As shown in FIG. 3H, the resin sealing structure is arranged in such a manner that the back surface of the resin sealing structure is directed upward. The groups of ball-shaped electrodes 8 are formed on the back surfaces of the effective regions 1b of the interconnection substrate board 1′ in the resin sealing structure.

Here, it is preferable that the ball mounting process (Step S6) is performed after the H/Sp cutting process (Step S5), in order to prevent the ball-shaped electrodes 8 from being crushed due to force applied to the resin sealing structure by the second blade 9.

### (Step S7: Wiring Board Cutting)

As shown in FIG. 3I, in order to divide the resin sealing structure in the second direction X, the interconnection substrate board 1′ and the sealing resin 4 are cut by the first disc-shaped blade 6 along the interconnection substrate board cutting line 1c in the second direction Y. Here, the cutting direction may be either the second direction Y or the direction opposite thereto. The interconnection substrate board 1′ and the sealing resin 4 are cut by the first blade 6 in a state that the center of the first blade 6 is displaced from the center of the region 5a by the preset displacement amount SL in a direction opposite to the first direction X.

Next, in order to divide the resin sealing structure in the first direction X, the interconnection substrate board 1′ and the sealing resin 4 are cut by the first blade 6 along the interconnection substrate board cutting line 1c in the first direction X. Here, the cutting direction may be either the first direction X or the direction opposite thereto. It may be also possible to cut along the interconnection substrate board cutting line 1c in the second direction Y after cutting along the interconnection substrate board cutting line 1c in the first direction X. As a result of this process, the resin sealing structure is divided into individual semiconductor devices. Here, the interconnection substrate board 1′ and the sealing resin 4 are cut by the first blade 6 in a state that the center of the thickness of the first blade 6 is coincident with the center of the region 1a extending in the first direction X.

In the interconnection substrate cutting process (Step S7), the first blade 6 is required to cut away the interconnection substrate board 1′ and the sealing resin 4. If a blade of the same type as the second blade 6 is used as the first blade 6, a cut section of the sealing resin 4 becomes coarse because the grinding grains are coarse. Therefore, as the first blade 6, it is preferable to use a blade provided with grinding grains such as diamond grains which are finer (smaller sized) than those of the second blade 9.

Moreover, it is preferable that the thicknesses (widths) of the first blade 6 and the second blade 9 are different from each other. Specifically, it is preferable that the thickness of the blade to be used in the subsequent process is thinner than that of the blade to be used in the preceding process. That is, in the present invention, it is preferable that the thickness of the first blade 6 is thinner than that of the second blade 9. Supposing that the thickness of the second blade 9 is A (not shown), a trench having the width of nearly A is formed in the H/Sp cutting process (Step S5). Further, it is assumed that the thickness of the first blade 6 is B (not shown). When B is smaller than A, the resin sealing structure can be cut without any burr, even if the first blade 6 is displaced more or less in the interconnection substrate cutting process (Step S7). This is because the cutting potion of the interconnection substrate board 1′ is positioned on an inner side than the cutting portion of the heat radiation plate 5′.

When the interconnection substrate cutting process (Step S7) is performed so that the resin sealing structure is cut, a plurality of semiconductor devices are obtained from the resin sealing structure to each have the interconnection substrate 1, the semiconductor chip 2, the bonding wires 3, the sealing resin 4, the heat radiator 5 and the group of ball-shaped electrodes 8, as shown in FIG. 3J. As a result, the center of the effective region 5b of the heat radiator 5 is displaced from the center of the effective region 1b of the interconnection substrate 1 by the preset displacement amount SL in the first direction X in each of the plurality of semiconductor devices.

The laser marking process (Step S4) is not limited to the order as described above, and may not be performed prior to the H/Sp cutting process (Step S5) but may be performed thereafter. For example, it may be performed after the interconnection substrate cutting process (Step S7).

Reasons of performing the H/Sp cutting process (Step S5) and the interconnection substrate cutting process (Step S7) will be described below.

First of all, it is assumed that the resin sealing structure as a whole is cut at once from a side of the interconnection substrate board 1′. In this case, stress directing from the side of the interconnection substrate board 1′ toward the side of the heat radiation plate 5′ would act on the heat radiation plate 5′ due to frictional force between the blade and the heat radiation plate 5′ of the resin sealing structure. Since there is no member for preventing deformation of the heat radiation plate 5′ on the side opposite to the sealing resin 4, it would be easy to form burr of the heat radiation plate 5′ in a direction from the side of the interconnection substrate board 1′ toward the side opposite to the heat radiation plate 5′.

On the other hand, in the present invention, the heat radiation plate 5′ is cut along the heat radiation plate cutting lines 5c in the first direction X and second direction Y in the H/Sp cutting process (Step S5). In this process, the sealing resin 4 is provided on the side applied with tensile force, of the heat radiation plate 5′ Thus, the deformation of the heat radiation plate 5′ is suppressed by the sealing resin 4. Moreover, since the heat radiation plate 5′ is cut along the heat radiation plate cutting line 5c in the first direction X and second direction Y in the H/Sp cutting process (Step S5), in the interconnection substrate cutting process, there is no need to cut the heat radiation plate 5′ at all or need to cut only a part of the heat radiation plate 5′ (Step S7). Therefore, the amount of cutting the heat radiation plate 5′ can be reduced in a direction opposite to a direction of the heat radiation plate 5′. As a result, it is possible to prevent burr from being formed at the edge portion of the heat radiation plate 5′ in the direction from the interconnection substrate board 1′ toward the heat radiation plate 5′

On the contrary, it is assumed that the resin sealing structure as a whole is cut at once from a side of the heat radiation plate 5′. In this case, the blade is pressed into a depth direction to reach the surface of the interconnection substrate board 1′ after the cutting edge thereof contacts the heat radiation plate 5′. For this period, stress acts on the heat radiation plate 5′ in a direction from the heat radiation plate 5′ to the interconnection substrate board 1′ due to tensile by frictional force between the blade and the heat radiation plate 5′. Since the blade is pressed deeply, the force applied to the heat radiation plate 5′ increases. Therefore, although the sealing resin 4 is provided on the rear side of the heat radiation plate 5′, the heat radiation plate 5′ is deformed and burr may be possibly formed at an edge portion of the heat radiator so as to direct from the heat radiation plate 5′ toward the interconnection substrate board 1′.

On the other hand, in the present invention, since the interconnection substrate board 1′ and the sealing resin 4 are cut in the interconnection substrate cutting process (Step S7), the heat radiation plate 5′ and a remaining part of the sealing resin 4 are merely required to be cut in the H/Sp cutting process (Step S5). Therefore, the force applied to the heat radiation plate 5′ can be reduced. Consequently, it is possible to suppress the forming of burr at the edge portion of the heat radiator.

As described above, according to the semiconductor device according to the embodiment of the present invention, by performing the H/Sp cutting process (Step S5) and the interconnection substrate cutting process (Step S7), it is possible to suppress the formation of burr directed in the third direction Z and the burr directed in a direction opposite to the third direction Z. Usually, if the burr is formed, the burr should be removed from the viewpoint of safety of a product. However, in the present invention, since the formation of the burr directed in the third direction Z or in the direction opposite to the third direction Z can be suppressed, a burr removing process is not needed. Thus, although the cutting process by a blade is required two times, the number of processes is not increased since the burr removing process is not needed.

The displacement of the center of the region 5a extending in the second direction y from the center of the region 1a extending in the second direction Y will be described below.

### Comparison Example

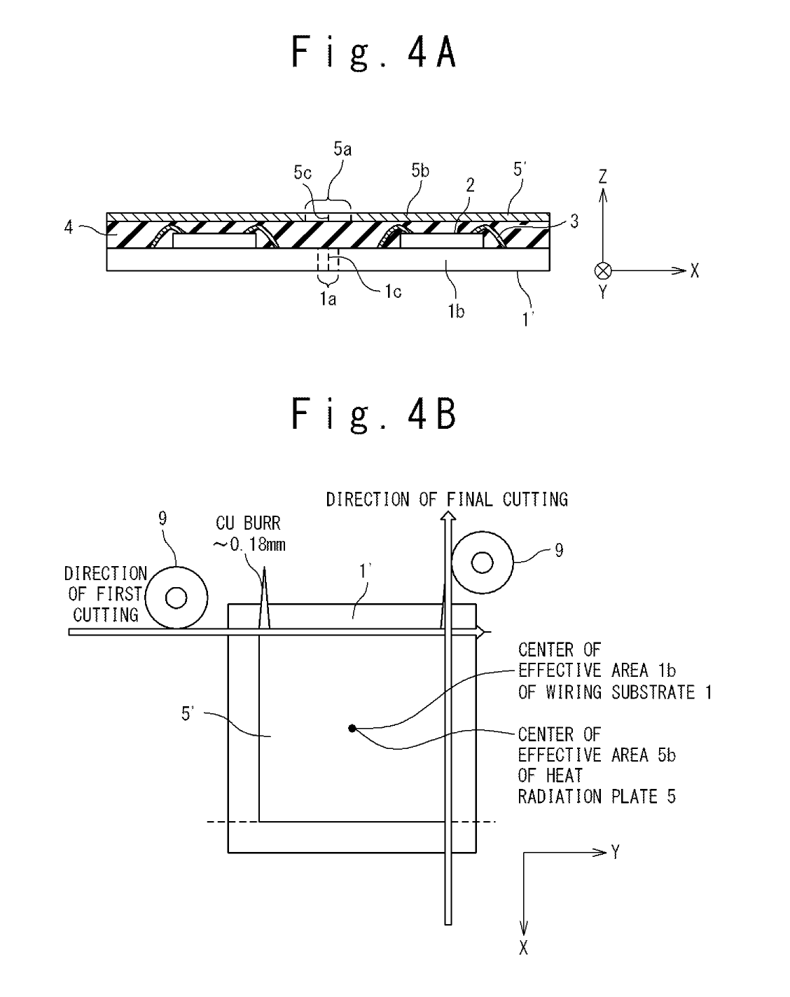

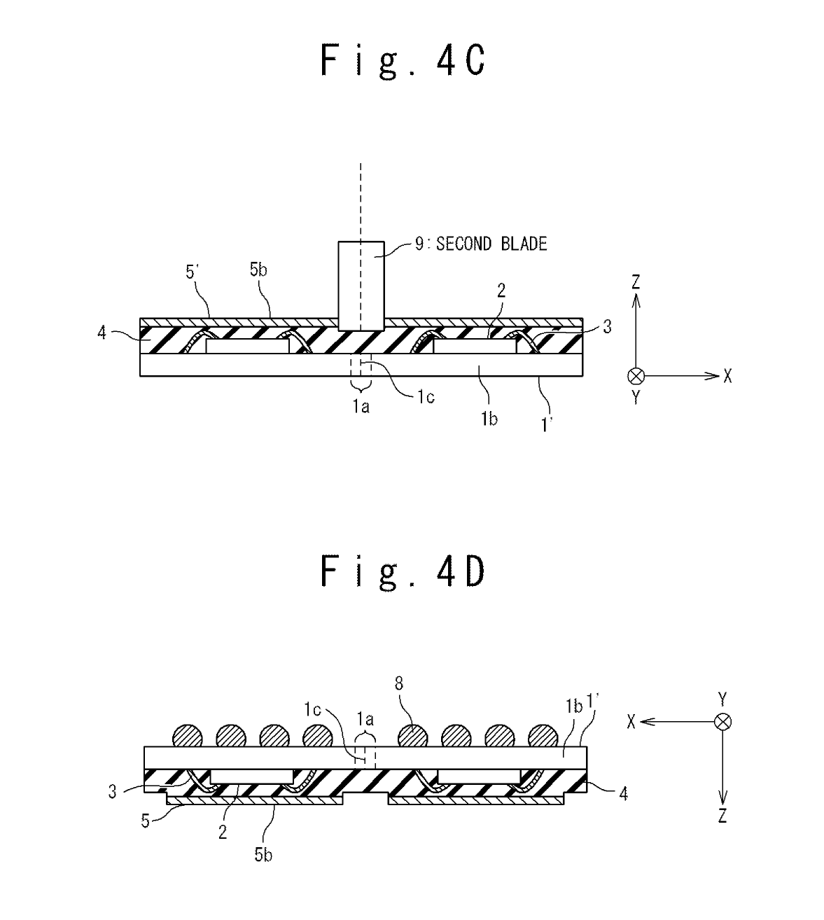

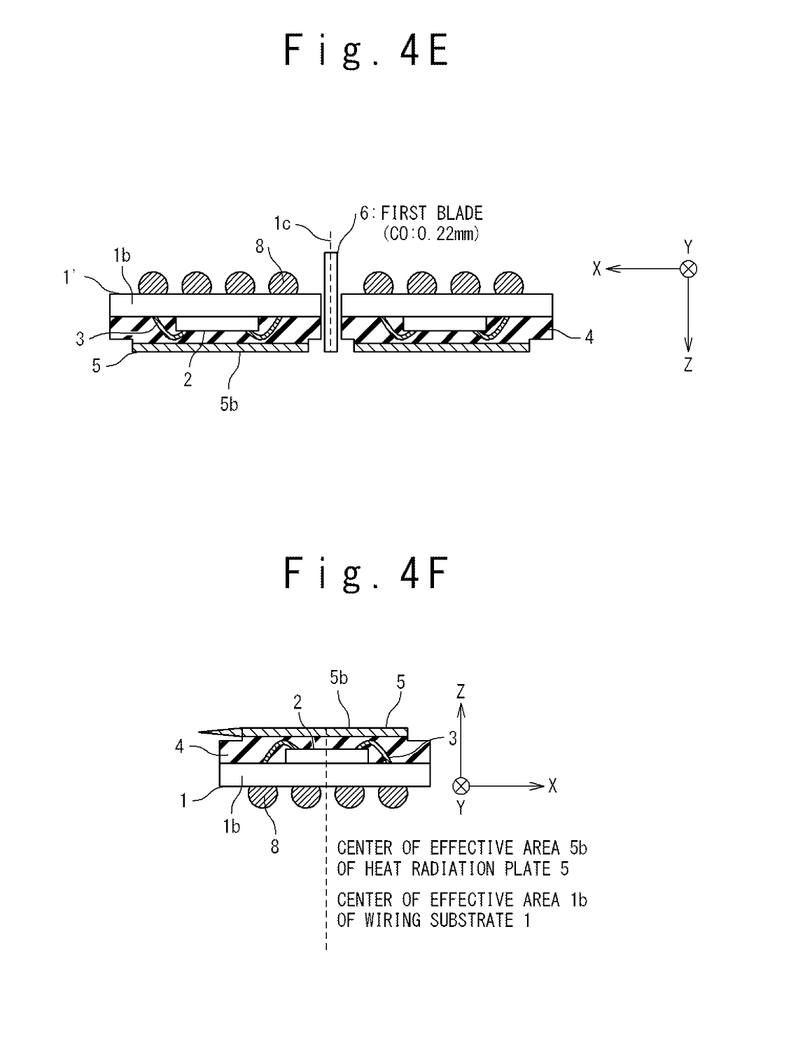

Initially, a comparison example with the embodiment of the present invention will be described in which the center of the region 5a extending in the second direction Y is coincident with the center of the region 1a extending in the second direction Y as shown in FIG. 4A.

In this case, the processes from the chip mounting process (Step S1) to the laser marking process (Step S4) are performed and then the H/Sp cutting process (Step S5) is performed as shown in FIGS. 4B and 4C. Subsequently, the ball mounting process (Step S6) is performed as shown in FIG. 4D and then the interconnection substrate cutting process (Step S7) is performed as shown in FIG. 4E. When the resin sealing structure (including the interconnection substrate board 1′, the semiconductor chips 2, the bonding wires 3, the sealing resin 4 and the heat radiation plate 5′) is cut in a matrix shape, a plurality of semiconductor devices are obtained from the resin sealing structure to each have the interconnection substrate 1, the semiconductor chip 2, the bonding wires 3, the sealing resin 4, the heat radiator 5 and the group of ball-shaped electrodes 8, as shown in FIG. 4F. In each of the plurality of semiconductor devices, the center of the effective region 5b of the heat radiator 5 is coincident with the center of the effective region 1b of the interconnection substrate 1.

Here, in the H/Sp cutting process (Step S5), the heat radiation plate 5′ is cut by the second blade 9 along the heat radiation plate cutting line 5c in the second direction Y in the first heat radiator cutting process. Subsequently, in the second heat radiator cutting process, the heat radiation plate 5′ is cut along the heat radiation plate cutting line 5c in the first direction X. At this time, stress acts on the heat radiation plate 5′ in a cutting direction due to frictional force between the second blade 6 and the heat radiation plate 5′. In the second heat radiator cutting process, since there is no member for preventing deformation of the heat radiation plate 5′ in a portion cut along the heat radiation plate cutting line 5c extending in the second direction Y when the heat radiation plate 5′ is cut in the first direction X, burr is easily formed toward the cutting direction of the heat radiation plate 5′. This burr would possibly protrude from an edge of the semiconductor device as shown in FIGS. 4B and 4F.

Here, assuming that the thickness of the second blade 9 is A0 and the thickness of the first blade 6 is B0, a distance C0 between the cutting line of the interconnection substrate board 1′ and the cutting line of the heat radiation plate 5′ is C0 (A0−B0)/2. Therefore, if the distance C0 is longer than the length BU of the burr, it seems that the burr does not protrude from the edge of the interconnection substrate 1. However, in a case of the heat radiation plate 5′ being copper (Cu), this method is difficult in practical use. In such a case, the length BU of burr is about 0.18 mm. Assuming that a permissible value of protrusion of the burr from the edge of the interconnection substrate 1 is 0.04 mm, the length C0 is about 0.14 mm in order that the burr does not protrude from the edge of the interconnection substrate 1. Therefore, the thickness A0 of the second blade 9 should be larger than the thickness B0 of the first blade 6 by 0.28 mm. However, if the thickness A0 of the second blade 9 is extremely large, a large load is applied to the resin sealing structure and the blade in the H/Sp cutting process (Step S5). In such a case, a problem arises that a peeling is caused between the heat radiation plate 5′ and the sealing resin 4, the life of the blade is reduced or a wear-out of a side is caused, and therefore it is not preferable.

Whereas, in the present invention, the center of the region 5a extending in the second direction Y is displaced by the preset displacement amount SL in the first direction X from the center of the region 1a extending in the second direction Y. In this case, the processes from the chip mounting process (Step S1) to the interconnection substrate cutting process (Step S7) are performed, and when the resin sealing structure is cut in a matrix shape, a plurality of semiconductor devices are obtained from the resin sealing structure. In each of the plurality of semiconductor devices, the center of the effective region 5b of the heat radiator 5 is displaced from the center of the effective region 1b by the preset displacement amount SL in the direction opposite to the final cutting direction, i.e., in the first direction X.

Also, in the present invention, although the burr is formed on the heat radiator 5 in the direction opposite to the first direction X, as shown in FIGS. 3F and 3J, since the center of the effective region 5b of the heat radiator 5 is displaced by the preset displacement amount SL in the first direction X from the center of the effective region 1b, the burr can be prevented from protruding from the edge of the interconnection substrate 1.

The preset displacement amount SL is determined based on the length SU of burr, the thickness A of the second blade 9 and the thickness 13 of the first blade 6. It is assumed here that the permissible length of protrusion of the burr from the edge of the interconnection substrate 1 is BUok (mm), in order to suppress the protrusion of burr, the preset displacement amount SL is expressed by the following equation:

SL=BU−Buok−(A−B)/2

Here, a derivation of this equation will be described with reference to FIG. 3K. FIG. 3K is an enlarged view in the vicinity of a portion of the burr shown in FIG. 3F. In FIG. 3K, since e=BU−BUok and e=A/2+SL−B/2, SL is obtained from the above equation.

By the way, as in the interconnection substrate cutting process (Step S7), it is desirable from the viewpoint of the burr that the region 1a for the interconnection substrate board cutting line is located inside the region 5a for the heat radiation plate cutting line 5c. That is, it is desirable that d is equal to or larger than 0 in FIG. 3K. Since d=A−B−e=A−B−(BU−Buok), the following relational equation should be satisfied. That is, since d 0, A−B BU−Buok is obtained. Accordingly, it is necessary that the thickness A of the second blade 9 is thicker than the thickness B of the first blade 6 by more than (BU−BUok). Here, since the preset displacement amount SL is equal to or larger than 0, through use of the equation of SL, the following equation is obtained:

2(BU−BUok)≧A−B

By this equation and the above equation, (A−B) should satisfy the following relational equation:

2(BU−BUok)≧A−B≧BU−BUok

In FIG. 3F, in the case of the heat radiation plate 5′ being copper (Cu), a procedure of calculating the preset displacement amount SL will be specifically described below. In the case of the heat radiation plate 5′ being made of copper, the length BU of burr is about 0.18 mm. It is assumed here that a permissible value of protrusion of the burr from the edge of the interconnection substrate 1 without any problem is 0.03 mm. Further, the thickness B of the first blade 6 is assumed to be 0.15 mm. Further, the thickness A of the second blade 9 is assumed to be in a range of 0.37 to 1.00 mm. Since BU−BUok=0.18-0.03=0.15 (mm), the value of (A−B) should satisfy a relational equation to be in the range of 0.15 A−B 0.30. Here, since B=0.15 (mm), the relational equation 0.30 A 0.45 is obtained. Since it is not desired to increase the thickness of the second blade 9, the minimum value 0.37 mm of A is selected. At this time, A−B=0.37-0.15=0.22 is obtained. Accordingly, the preset displacement amount SL is expressed below:

SL=BU−BUok−(A−B)/2=0.15−0.11=0.04 Thus, the preset displacement amount SL becomes 0.04 mm. Therefore, in the present invention, as shown in FIGS. 3D, 3F and 3J, by displacing the center of the effective region 5b of the heat radiator 5 from the center of the effective region 1b of the interconnection substrate 1 by 0.04 mm in the first direction X, the protrusion of burr from the edge of the interconnection substrate 1 can be suppressed.

As described above, in the semiconductor device by the embodiment of the present invention, the thickness of the first blade 6 is thinner than the thickness of the second blade 9, and the center of the region 5a for the heat radiation plate cutting line 5c extending in the second direction Y is displaced by the preset displacement amount SL in the first direction X from the center of the region 1a for the interconnection substrate board cutting line 1c extending in the second direction Y, whereby exposure of the burr in the final cutting direction can be suppressed. Thus, in the present invention, similarly to the first effect, a burr removing process is not needed. Therefore, although setting of the preset displacement amount SL is needed, the number of processes does not increase since the burry removing process is not needed.

In the present invention, although the H/Sp cutting process (Step S5) is performed in advance and the interconnection substrate cutting process (Step S7) is performed thereafter, the order of the processes is not limited to this. Since it is sufficient as long as a plurality of semiconductor devices can be obtained from the resin sealing structure, the interconnection substrate cutting process (Step S7) may be performed in advance and the H/Sp cutting process (Step S5) may be performed thereafter. In this case, it is preferable that the second blade 9 does not reach the heat radiation plate 5′ in the interconnection substrate cutting process (Step S7), and a half-cut process may be performed similarly to the H/Sp cutting process (Step S5). That is, a rate of the cutting may be appropriately determined as long as the plurality of semiconductor devices can be obtained from the resin sealing structure.

Moreover, in the present invention, the semiconductor device of a BGA type has been described as an example in which the semiconductor chip 2 and the interconnection substrate board 1′ are connected through the bonding wires 3. However, the present invention is not limited to this type. For example, a stacked MCP (Multi Chip Package) type of the semiconductor device may be adopted in which the plurality of semiconductor chips 2 are laminated on the interconnection substrate board 1′, or a planar MCP type of the semiconductor device may be adopted in which the plurality of semiconductor chips 2 are placed on the interconnection substrate board 1′. In the semiconductor device of the stacked MCP type/planar MCP type, the plurality of semiconductor chips 2 are provided in the semiconductor device, and each of the plurality of semiconductor chips 2 is connected to the interconnection substrate 1 through the bonding wires 3.

Moreover, in the present invention, a FCBGA (Flip-chip Ball Grid Array) type of the semiconductor device or COC (Chip on Chip)/Wire Mixed type of the semiconductor device may be adopted. In the FCBGA type of the semiconductor device, the semiconductor chip 2 is arranged in such a manner that the electrode formation surface thereof faces the interconnection substrate 1. In the COC (Chip on Chip)/Wire Mixed type of the semiconductor device, the plurality of semiconductor chips 2 are provided inside thereof. The plurality of semiconductor chips 2 includes a first semiconductor chip that is connected to the interconnection substrate 1 through the bonding wires 3 and a second semiconductor chip that is formed on the first semiconductor chip. The second semiconductor chip is arranged in such a manner that the electrode formation surface thereof faces the first semiconductor chip. In the case of the FCBGA type or COC (Chip on Chip)/Wire Mixed type of the semiconductor device, the heat radiation plate 5′ may be either contacted or not contacted with a back surface of the semiconductor chip 2. However, the heat radiation plate 5′ is preferably contacted with the back surface of the semiconductor chip 2 from the viewpoint of a heat discharge property.

Moreover, in the present invention, as an application thereof, when the laser marking process (Step S4) is performed prior to the H/Sp cutting process (Step S5), a laser prescribing process may be added in the laser marking process (Step S4) so that a part or an entire of the heat radiation plate cutting lines 5c in the first direction X and the second direction Y of the heat radiation plate 5′ is cut away by a laser. Since the laser is used in the laser prescribing process, although the time for performing the same is not shortened, the formation of burr in the final cutting direction can be suppressed.

Moreover, in the present invention, as an application thereof, when the laser marking process (Step S4) is performed after the H/Sp cutting process (Step S5), a laser burr removing process may be added in the laser marking process (Step S4) so that a part or an entire of the heat radiation plate cutting lines 5c in the first direction X and the second direction Y of the heat radiation plate 5′ is cut away by a laser. Since a laser is used in the laser burr removing process, although the time of performing the same is not shortened, the formation of burr in the final cutting direction can be suppressed.

What is claimed is:

1. A method of manufacturing semiconductor devices, wherein a resin sealing structure comprises an interconnection substrate board, semiconductor chips mounted on said interconnection substrate board, a heat radiation plate arranged above said semiconductor chips, and sealing resin provided between said heat radiation plate and said interconnection substrate board, the method comprising:
cutting said heat radiation plate by a plate cutting blade in a first direction along a first heat radiation plate cutting line;
cutting said heat radiation plate by said plate cutting blade in a second direction orthogonal to the first direction along a second heat radiation plate cutting line orthogonal to the first heat radiation plate cutting line, after said cutting said heat radiation plate by said plate cutting blade in the first direction; and
cutting said interconnection substrate board and said sealing resin along first and second interconnection substrate board cutting lines by a substrate board cutting blade in the first direction and the second direction, respectively, to divide said resin sealing structure into said semiconductor devices,
wherein each of said semiconductor devices comprises an interconnection substrate, said semiconductor chip mounted on said interconnection substrate, said sealing resin provided to cover said semiconductor chip and said interconnection substrate, and a heat radiator,
wherein said second heat radiation plate cutting line and said second interconnection substrate board cutting line correspond to each other in position in a third direction orthogonal to the first direction and the second direction, and
wherein said first heat radiation plate cutting line is displaced from said first interconnection substrate board cutting line by a preset displacement amount in a direction opposite to the second direction.

2. The method according to claim 1, wherein said plate cutting blade is thicker than said substrate board cutting blade.

3. The method according to claim 1, wherein a center of said heat radiator of said semiconductor device is displaced from a center of said interconnection substrate of said semiconductor device by the preset displacement amount in the direction opposite to the second direction.

4. The method according to claim 1, wherein said preset displacement amount is determined based on a length of burr, a thickness of said plate cutting blade, and a thickness of said substrate board cutting blade, wherein the burr is formed to protrude from an edge of said heat radiator section.

5. The method according to claim 4, wherein the preset displacement amount SL satisfies the following equation:
SL=BU−Buok−(A−B)/2
where the length of burr is BU, a permissible value of protrusion of the burr is BUok, the thickness of said plate cutting blade is A, and the thickness of said substrate board cutting blade is B.

6. The method according to claim 5, wherein the following equation is satisfied:
A−B BU−Buok

7. The method according to claim 4, wherein a center of a region for the second heat radiation plate cutting line is coincident with a center of a region for the second interconnection substrate board cutting line in a third direction orthogonal to the first and second directions.

8. The method according to claim 4, wherein said cutting by said substrate board cutting blade is performed after said cutting by said plate cutting blade.

9. The method according to claim 8, further comprising:
forming a group of ball-shaped electrodes on a surface of said interconnection substrate board on a side opposite to said sealing resin.

10. The method according to claim 9, wherein said forming a group of ball-shaped electrodes is performed between said cutting by said substrate board cutting blade and said cutting in the first direction by said plate cutting blade.

11. The method according to claim 4, wherein said plate cutting blade has grinding particles coarser than said substrate board cutting blade.

12. A semiconductor devices comprising:
a semiconductor chip mounted on a front surface of an interconnection substrate;
a heat radiator arranged above said semiconductor chip; and
sealing resin provided between said heat radiator and said interconnection substrate,
wherein a center of said heat radiator is displaced from a center of said interconnection substrate by a preset displacement amount in a predetermined direction.

13. The semiconductor device according to claim 12, further comprising:
a group of ball-shaped electrodes formed on a back surface of said interconnection substrate.

14. The semiconductor device according to claim 12, further comprising:
a bonding wire configured to connect said semiconductor chip and said interconnection substrate and sealed by said sealing resin.
